(19) United States
(12) Patent Application Publication
(10) Pub. No.: US 2012/0014524 A1
(43) Pub. Date: Jan. 19, 2012

(54) Distributed bass

(76) Inventor: Philip Vafiadis, St. Peter (AU)

(21) Appl. No.: 12/311,648

(22) PCT Filed: Oct. 8, 2007
(86) PCT No.: PCT/AU2007/001522

§ 371 Date: Sep. 13, 2011

(30) Foreign Application Priority Data
Oct. 6, 2006 (AU) 2006905564

(51) Int. Cl. H03G 5/00

(52) U.S. Cl. 381/17

(57) ABSTRACT

Low frequencies in an audio source are extracted and reintroduced into the remaining audio channels and a consequence of one possible setting of the invention is that the low frequencies are shared evenly across the two or more speaker thus avoiding the use of a special low frequency speaker known as a sub woofer. A further outcome of the use of the invention is the substantially even distribution of LFE audio within a listening volume and that in some instances the actual and possibly the perceived total sound pressure level of the LFE audio is greater from multiple distributed speakers than that of a single sub woofer speaker. Low frequency audio provided to multiple speakers, as proposed in this invention, can work within room boundaries to provide more effective listening positions, better sound quality and low frequency reception having dramatically reduced response ripple, i.e., dips will not be as deep, and peaks not as high. Low frequency equalisation and magnitude dependant variable frequency equalisation is used in conjunction with signal distribution and signal summing before the signal reaches one or more speakers while eliminating the need for a sub woofer speaker.

This invention relates to audio signal processing and in particular to a variation to sound reproduction processes associated with stereo and surround sound systems.

### BACKGROUND

There exists at the present time a large variety of audio stereo and surround sound systems. The surround sound systems in particular are designed to create theatre-like audio surround sound in a home or home theatre environment. Clearly, the success of the surround sound experience will depend on the quality of equipment, the way it is set up and the acoustic properties of the environment.

However, not all environments are alike and not all budgets can afford the ideal equipment and set-up options.

The increasingly complex nature of audio recording and audio reproduction including digital and analogue sound encoding onto recordings provides great advantages to the way in which audio visual presentations such as movies and the like are provided to home and commercial users. Relatively simple mono and stereo audio sound systems were the forerunners of audio systems that now include matrix (synthetic) surround sound where the standard stereo audio channels were transformed into multi-channel signals. Later, the stereo channels were specially coded so that multiple audio channel signals (eg Left, Right, Centre and Surround Left and Right channels sometimes referred to as “Surround Left and Right”) were made available to five speakers located within the listening environment. The speakers were full frequency range capable however with typical systems only the Left, Centre and Right speakers were of a full range capacity and in many cases the low frequency reproduction of those speakers suffered because the surround speakers were not optimised for those low frequencies.

With the advent of the need to provide speakers for these and additional audio channels, additional speakers for the surround locations were required; however they were not always of the full frequency range type in keeping with cost reduction measures to make the additional speakers more affordable in the overall package.

As encoding and decoding schemes improved and direct digital audio sources were used, it is now typical for a home user to use a digitally encoded audio visual data carrier such as a Digital Versatile Disc (DVD) as the source of the audio surround sound channels. A variety of encoding and corresponding decoding standards exist (for example Dolby Digital, DTS, DVD-Audio, Super Audio Compact Disc, MP3 Surround as typically used in consumer products and Dolby Digital, DTS and Sony Dynamic Digital Sound in theatres), but consumers (users) know that at a minimum they would want a 5.1 channel audio system which provides Front Right, Front Left, Front Centre, Surround Left and Surround Right audio channels (5.0 channels) plus a Low Frequency Effects (LFE) channel (0.1 channel).

Such a system thus requires a speaker for each of the six channels. The frequency response of each of the speakers for the 5.0 channels is generally designed to reproduce a wide range of audio frequencies with the exception of the lower frequencies, while the speaker specifically designed to cover the low range of audio frequencies and handle Low Frequency Effects is termed variously a subwoofer, sub and woofer. The LFE channel specifically included in DVD programmes and may include frequencies in the range 20 to 150 Hz but higher and lower frequencies are possible.

There presently exist more advanced encoding and decoding capabilities which can provide 6.1 and even 7.1 surround sound capability incorporating single or double Centre Rear or Surround Rear speakers.

Typically, although not necessarily, the rearwardly located (that is rearward of the listener) surround speakers have the characteristic of delivering less sound pressure than the front set of speakers, but this may generally be due to the creators of the surround tracks using less volume behind the scene than in front. In any event a surround sound speaker is generally physically smaller than the subwoofer speaker and by itself not able to recreate the sound pressure level of the generally lager subwoofer speaker at low frequencies.

Subwoofer speakers can be passive, that is use only the audio signal provided to activate the speaker. Or as is typical, subwoofer speakers are active (powered), that is the subwoofer package includes a mains powered amplifier and the electronics to amplify only the LFE frequencies provided to it.

A surround sound speaker is prone to distort when driven by high level signals (high level low frequency sounds) when trying to create a commensurate high sound pressure level low frequency effect.

The LFE track is typically used as a sound and mood creator track and is devoted to low frequency effects such as rumbling, cracking, drumming, bells, explosions, gunfire and the like. Good LFE signal reproduction requires an expensive, typically individually powered and amplified subwoofer speaker, if the LFE channel is not otherwise amplified by the decoder/receiver amplifier device that powers the other speakers.

What a listener hears is a combination of direct sound from each speaker (including a subwoofer when used is direct listening position) and also reflected sound from the walls and furniture from all of the speakers. Phase distortion is a concern that good system design and adjustments either at the sound processor end or at the subwoofer for example can eliminate or substantially reduce.

A single subwoofer typically radiates energy which has a long wave length and to a listener there is little indication as to where the sound energy is emanating hence there is less importance in the positioning of the subwoofer, while the surround sound speakers have a narrower sound pressure dispersion characteristic and are very directional and their positioning with respect to the listener is critical. The result is that when a single subwoofer is used with any number of surround speakers, the reverberant field of the room has a spectrum that is heavily bass biased. This is difficult to equalise as this occurs in the time domain (reflected sound path lengths are longer than the direct distance from a speaker to a listeners ears).

If the subwoofer output is reduced with respect to the surround speaker so the bass biased reflected sound is in correct proportion to the direct sound from the speakers, the sub woofers' direct sound will be perceived as light.

Short of very sophisticated room treatments or very sophisticated Digital Signal Processing or beam steering there is no current solution to the bass bias situation.

Even if expensive arrangements were employed, they will only eliminate the problem at only one listening position, which is not practical or realistic in typical environments where more than one listener is present or the listener chooses not to occupy the same position each time.

It may also be possible to supply more than one subwoofer speaker or one subwoofer speaker at each location of the other speakers in the arrangement but that becomes expensive and impractical when cost and space considerations are substantial issues in all but the most expensive arrangements.

It is the additional cost and space requirement of the typically one LFE speaker which it is proposed by the inventor to be eliminated by the use of the invention described herein. Furthermore it is possible for the invention to provide overall greater sound pressure levels than otherwise obtainable from a dedicated LFE speaker while typically driving the surround speakers within their linear range of operation and better conforming the low frequency signals to those of the other speakers in the environment.

A detailed description of one or more preferred embodiments of the invention is provided below along with accompanying figures that illustrate by way of example the principles of the invention. While the invention is described in connection with such embodiments, it should be understood that the invention is not limited to any embodiment. On the contrary, the scope of the invention is limited only by the appended claims and the invention encompasses numerous alternatives, modifications and equivalents. For the purpose of example, numerous specific details are set forth in the following description in order to provide a thorough understanding of the present invention. The present invention may be practiced according to the claims without some or all of these specific details. For the purpose of clarity, technical material that is known in the technical fields related to the invention has not been described in detail so that the present invention is not unnecessarily obscured.

Throughout this specification and the claims that follow unless the context requires otherwise, the words ‘comprise’ and ‘include’ and variations such as ‘comprising’ and ‘including’ will be understood to imply the inclusion of a stated integer or group of integers but not the exclusion of any other integer or group of integers.

The reference to any prior art in this specification is not, and should not be taken as, an acknowledgment or any form of suggestion that such prior art forms part of the common general knowledge.

### BRIEF DESCRIPTION OF THE INVENTION

In a broad aspect of the invention an audio processing system for receiving filtered multiple audio channel signals which have been filtered according to settings for the filters applied to the multiple audio channels to create a low frequency channel and one or more channels excluding low frequencies intended for supply to respective multiple signal-to-sound transducers including; a processing device for equalising the low frequency audio channel signal and distributing equalised audio low frequency signals to be summed with a filtered audio channel signal wherein the summed signal is intended to be received by a respective multiple signal-to-sound transducer.

In a further aspect, the invention further includes an audio processing system wherein the low frequency audio channel is distributed to be summed with all or predetermined ones of the filtered audio channel signals.

In a further aspect of an audio processing system the low frequency audio channel is distributed at a level 1/n to each of it audio channels.

In yet a further aspect of an audio processing system the low frequency audio channel is distributed at a predetermined level to be summed with all or predetermined ones of the filtered audio channel signals.

In an aspect of an audio processing system an audio amplifier for amplifying each of said mixed audio channels and providing said amplified audio channel to a said signal-to-sound transducer is arranged wherein the sound pressure level generated in said sound transducers from the low frequency audio channel is independent of the predetermined listening level.

In an other aspect of the invention an audio processing system for processing multiple audio channel signals, includes a pre-filtering device which receives the multiple audio channel signals and applies at least one filter to each channel according to settings for the filter to create a low frequency channel and one or more audio channels that do not have low frequencies, the one or more audio channels intended for supply to respective multiple signal-to-sound transducers; and a processing device for equalising the low frequency audio channel signal and distributing equalised audio low frequency signals to be summed with a filtered audio channel signal wherein the summed signal is to be received by a respective multiple signal-to-sound transducer.

In yet another aspect of the invention a subwoofer speaker elimination arrangement in a sound system having one or more signal-to-sound transducers to receive a respective audio channel signal including a low frequency effects signal (LFE), includes, an LFE signal equalisation means for receiving the LFE audio channel signal output for equalisation and distribution amongst a plurality of LFE equalisation signal outputs equal in number to the number of audio channel signals less the LFE channel; and an audio signal mixer for each of said plurality of surround sound audio channel signals, each said audio mixer having a first input for receiving one of said plurality of audio channel signals not being an LFE audio channel and a second input for receiving an equalised LFE audio channel signal and an output for outputting a mixed audio signal for a respective audio signal channel.

A subwoofer speaker elimination arrangement according to an aspect of the invention further includes an audio amplifier for amplifying each of said mixed audio channels and providing said amplified audio channel to a said signal-to-sound transducer wherein the sound pressure level generated in said sound transducers from the LFE audio channel is independent of the predetermined listening level.

Throughout the specification unless the context applies otherwise, the words “comprise” and “include” and variations such as “comprising” and “including” will be understood to imply the inclusion of the stated integer or group of integers but not the exclusion of any other integer or group of integers.

Specific embodiments of the invention will now be described in some further detail with reference to and as illustrated in the accompanying figures. These embodiments are illustrative, and not meant to be restrictive of the scope of the invention. Suggestions and descriptions of other embodiments may be included within the scope of the invention but they may not be illustrated in the accompanying figures, or alternatively features of the invention may be shown in the figures but not described in the specification.

### BRIEF DESCRIPTION OF THE FIGURES

FIG. 1 depicts a typical 6.1 surround sound channel processing and speaker configuration in a home environment;

FIG. 2 depicts a system block diagram of an embodiment of the invention showing the use of a low frequency equalisation, distribution and summing functional block;

FIG. 3 depicts a system block diagram of a further embodiment of the invention showing the use of a low frequency magnitude and variable equalisation including a speaker size information source functional block, along with a distribution and summing functional block;

FIG. 4 depicts a system block diagram of a yet further embodiment of the invention showing the use of an audio signal pre-filtering stage located prior to the low frequency equalisation, distribution and summing functional block; and

FIGS. 5a and 5b depict an equal loudness plot of intensity (dB) versus frequency according to the normal human ear where FIG. 5b is the annotated version of the same plot in FIG. 5a.

### DETAILED DESCRIPTION

The following description provides as an example system a 6.1 surround sound channel arrangement.

This is merely an example system to which embodiment(s) of the invention is/are applied. The principles applied are equally applicable to any number of multiple audio channels including stereo and prior matrix surround sound systems and 5.1, 7.1 and any future configuration of surround sound channels. It is also possible to apply the principles and apparatus of the invention to a single audio sound source where is it desired to redistribute a particular band (in this specification the lower audio frequency band) to selected speakers of a multiple speaker installation.

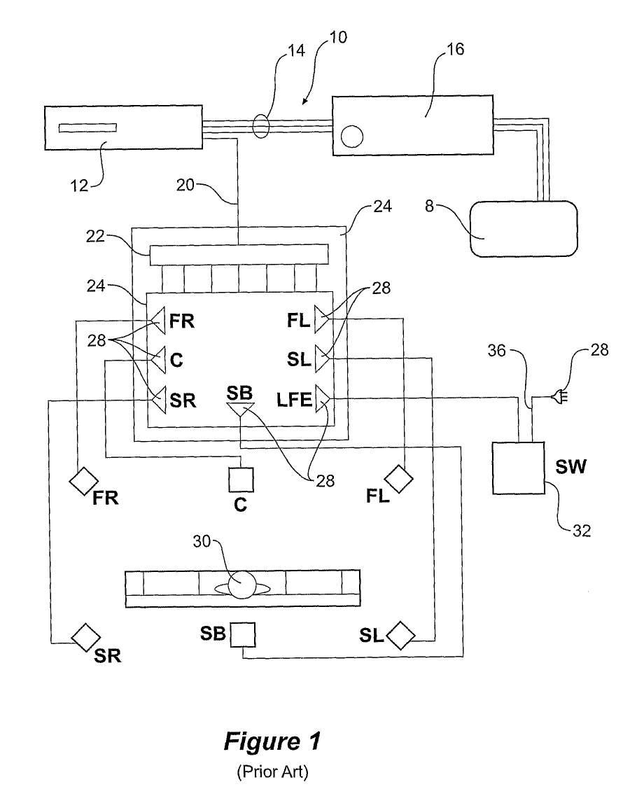

FIG. 1 depicts a prior art 6.1 channel surround sound system 10 consisting of a 6.1 channel audio source and a video source, in this example a DVD player 12. The audio visual source could be supplied any number of devices including terrestrial television set top box, HD or BluRay DVD player, stereo record turntable, radio receiver, digital audio player, etc.

The video signal output of the DVD player is provided into cabling 14 comprising three channels, being luminance, difference R-Y, difference B-Y, also referred to (Y, Pr, Pb). The video output of the DVD is shown as connecting directly to a video processor 16 which could be incorporated into the video display device 18 or in a separate device commonly referred to as a “receiver” which is designed to receive, process and switch video and audio from and to various sources and destinations (not shown in this figure to reduce the complexity of the illustration). There are many other forms of video signal output but this is not the focus of the invention disclosed herein.

Another output of the DVD device 12 is audio output 20. For the purposes of this example the audio is a digital 6.1 channel surround sound bit stream carried upon an optical digital communications link between the DVD device and a receiver device 24 there being many other audio signal outputs to choose from when using a DVD device and equally many audio inputs when using a receiver. The receiver device is typically the same as the video receiver mentioned previously, the receiver designed to process both audio and video signals.

The digital audio signal output is coupled to the above mentioned optical digital communications link 20 and received by an audio processor 22 within the receiver 24. The audio processor is designed to decode the digital audio input stream into separate Front Left (FL), Front Right (FR), Front Centre (FC), Surround Left (SL), Surround Right (SR), Surround Back (SB) and LFE surround sound audio channel signals (a total of seven channels).

All audio processors with a Dolby Digital or DTS license are required have a feature called ‘Bass Management”. The bass management feature of the receiver must be able to filter the bass frequencies (those below a predetermined cross-over frequency using an appropriate audio frequency filter) out of the primary 5 to 6 audio channels available after decoding the audio signal. The receiver enables that facility by having the user set the receiver audio channel processing to a setting called “small” for each of the channels in this example being the six surround audio channels Front Left (FL), Front Right (FR), Centre (C), Surround Left (SD), Surround Right (SR) and Surround Back (SB) that are typically provided to six speakers (not always but often the speakers are full frequency response speakers). The terms “small” and “large” refer to the respective dynamic ranges of the speakers, not their physical size.

The bass frequencies that exist in those channels and the special Low Frequency Effects (LFE) signals available from the audio source (typically just a part a digital bit stream as are all the other channels) are destined to be supplied to a subwoofer speaker (SW). A sub woofer speaker is designed to handle the low frequencies including all those in the LFE signal and is typically powered separately and has its own low frequency amplifier because it is dedicated to reproducing the LFE channel which is purposely placed into the source audio, as described previously.

In the prior art system depicted in FIG. 1, used herein as an example of a surround sound system, the audio processor will have been set-up with the audio signals directed to the surround speakers to be “small” because it is intended to use the LFE channel with a subwoofer speaker.

Each of the signals referred to is provided to an amplifier 28 of its own and the amplified signal is supplied to a sound transducer (speaker) each shown by the labels; FL, FR, C, SL, SR, SB and SW as appropriate. Sometimes the LFE channel is only provided to a pre-amplifier because the sub woofer will have its own amplifier as stated previously.

Some or all of these speakers can be full frequency response speakers. In the particular case of stereo sound listening, it will be desirable that the FR and FR speakers be of a quality higher than the others.

The speakers FL, FR, C, SL, SR, SB and SW are often positioned about the listening position 30 as shown pictorially in FIG. 1. There exists a great deal of science and personal preference in the final positioning of speakers so there is unlikely to be a universal placement scheme.

The location of the SW speaker 32 may be critical as inappropriate positioning will cause the high pressure level low frequencies emitted by the speaker to be adversely affected by the reverberation characteristic of the room, resulting in a listening spectrum that is heavily bass biased or alternatively too soft and lacking in definition but sub woofer placement is generally considered less critical than placement of the other speakers in a system.

As mentioned above, the LFE amplifier (having amplification equivalent to other channels) can sometimes be omitted from a receiver device. Instead, there is a low level signal amplifier (pre-amp) within the receiver which supplies the LFE audio signal to an active mains powered LFE amplifier in the SW speaker enclosure 32 that provides its own amplification. The additional cord 26 shown in FIG. 1 connects using plug 28 to an external AC power source to provide power to the LFE amplifier in the sub woofer.

The sound pressure level experienced by a user will depend on the centrally set volume setting and on the distance of each speaker from them. It is known that the human ear interprets sound pressure levels differently for different frequencies, and of course each person has their own individual hearing response, so for the purposes of discussion and example there are standardised human hearing responses used for the setting of the equalisation of devices that can be so adjusted.

Receiver devices are designed with many features one of which is the ability to set the range of frequencies they provide to each speaker. As described above and elsewhere, it is typical in a surround sound set-up to designate all the full frequency speakers as “small” meaning that the speakers are supplied with frequencies above a predetermined cross-over frequency (typically 80 Hz or 120 Hz) and the frequencies below this are processed and sent to the LFE channel output destined for the LFE speaker along with the LFE signal if present.

The prior art arrangement disclosed in FIG. 1 can also be used to listen tot stereo audio, which is still important to certain users of this type of equipment. IN that situation the receiver can be set to supply the received stereo signals to only the FR and FL speakers while disabling the other channels so as to eliminate any possible inference from their operation within the receiver to the stereo signal processing.

As a precursor to the following description of embodiments of the invention it is useful to describe the intent of the invention which is to eliminate the use of a sub woofer from an audio distribution system.

Thus the invention can be applied to a variety of audio distribution and listening arrangements. One example given particular emphasis in this specification is the home theatre multiple audio channel environment and the processing that is typically provided by a surround sound receiver.

However, it is possible to apply the principle of the invention to a further situation; such as for example, when listening to a stereo audio source. Stereo listening requires a reliance on the frequency reproduction ability of just two speakers (FR and FL) and especially in the low frequency range of those speakers and sometimes just one of those speakers when the low frequency audio signal is confined to one channel, either the left or right channel. The invention makes it is possible to apply a low frequency filter to extract the low frequencies in both the stereo channels and equalise and distribute that low frequency signal to all the speakers typically available. That is the low frequency signal is provided not only the FL and FR speakers, but also the C, SR, SL and SB speakers. The effect produced by applying the invention in this way is for the listener to experience the low frequencies that may otherwise have been attenuated, distorted or audibly compromised by reliance on one or both of the FR and FL speakers.

The principle of the invention could also be applied to the distribution of a mono audio signal to many speakers. Mono distribution would typically occur in a public address system where either the original audio source is mono (as when a speaker uses a microphone) or a stereo source mixed to a mono channel for distribution amongst multiple speakers. By filtering out the low frequencies, equalising them and distributing them selectively amongst the multiple speakers it is possible to provide a different listening experience for those located within hearing distance of one of more of the speakers. This could for example provide for a sound staged aural experience where the crowd, while being addressed may have the higher frequencies deliver to them via a set of speakers near the stage and the lower frequencies delivered to all the speakers or a selected subset of them thus providing the summed sound pressure level of those low frequencies to some effect during the address.

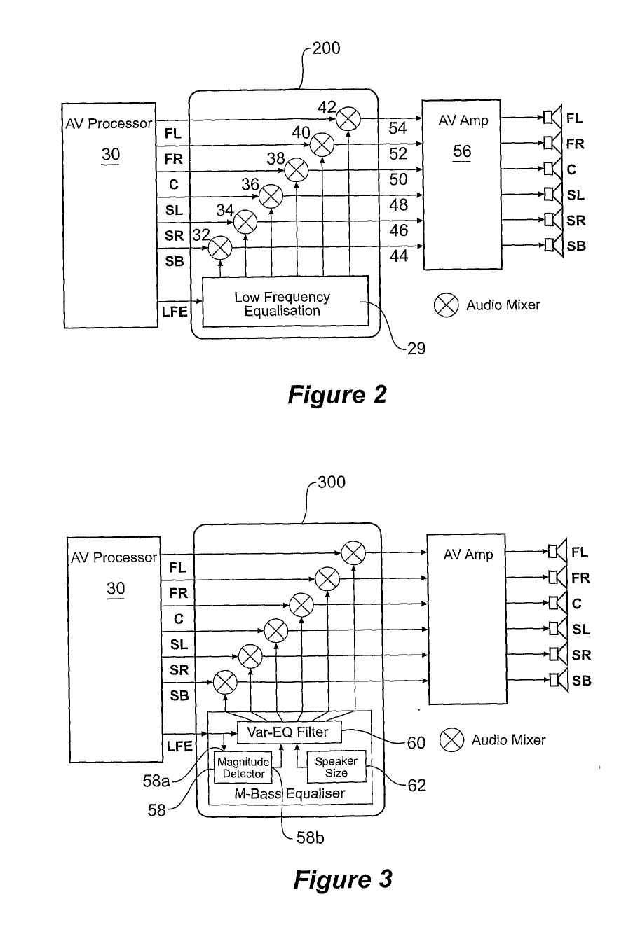

FIG. 2 depicts an audio processor 30 that can be equivalent to the audio processor 22 illustrated in FIG. 1, or as is most likely to be the implementation of the invention, the audio processor 30 will be used in the typical audio receiver. The outputs of the audio processor 30 are multiple surround sound audio channel signals identified as Front Left, Front Right, Front Centre, Surround Left, Surround Right, Surround Back and LFE. These signals are obtained by one or more processes performed within the processor but may also involve minimal processing so as to allow the received signal the simplest path through the receiver to the speakers. Details of the transformation of received signals into the various audio channels are not the subject matter of this invention but are well understood by those of skill in the art.

In this embodiment the audio processor 30 is supplied by others and in this particular embodiment the processor is a surround sound processor designed to receive audio and video (although this invention deals with the audio signals). Audio processors of this type have extensive and sophisticated filtering circuitry which is not discussed in detail herein as it is well known to those of skill in the art, however, the application of one or more of those filters is selectable by the user of the receiver via a simple menu which typically does not require the user to understand the intricacies of the circuitry.

The audio processors can be controlled to direct all of the LFE signals from all the multiple surround sound audio channels to the LFE output. This can be achieved using normal processor functionality as described previously in particular using filters.

In the embodiment depicted in FIG. 2, the LFE audio signal channel is provided to an equalisation means 29. In one embodiment the equalisation means equalises and distributes the LFE audio across all of the audio channels in equal proportions but variants are possible in accord with the description provided herein.

Equalisation may be in the form of frequency enhancement or attenuation across one or more bands within the audio frequency spectrum received for processing or involve no changes at all, except that in this embodiment of the invention, the equalisation means will provide a one to n split, when there are n surround sound audio channels to be distributed to. The level at which the split occurs can be set according to one or more rules, one of which is that the LFE signal is weighted evenly across all the audio channels, and in another example, the weighting is set individually for each channel. Distribution in this embodiment includes splitting or providing unitary amplification of the incoming LFE audio signal six ways that is maintaining the levels of the incoming signal without changes. The settings as to the equalisation and distribution proportions may be derived by way of experimentation and the desirable characteristics to be achieved by those settings determined by way of determining preferences and derivation of a standard expectation for listeners. There will be no single equalisation and distribution arrangement to suit all circumstances.

As discussed above the ratio of the split/boost may be even amongst the six channels or it may vary depending on the type of channel it is and speaker it is destined for.

The equalisation of the signal (frequency enhancement or attenuation) changes the tone and harmonics of an audio signal selected bands of frequencies in the audio signal.

There are a number of different schools of thought as to what bandwidth the LFE channel should have—the lower extremity is generally agreed to be less than 30 Hz, while the upper extremity is typically 80 or 120 Hz, but the low frequency upper bound is also sometimes considered to be 300 Hz.

For the purposes of discussion the upper or cross-over point when using a subwoofer speaker to transducer the LFE signal is set at 120 Hz. For the purposes of illustration in this embodiment, the bandwidth of the frequencies filtered out for processing in accordance with the invention is nominally 30 to 120 Hz and thus readily includes those frequencies that are part of the LFE channel, if present, and the low frequencies that may be part of the audio signals received. It is known however that the boundary of the frequencies being filtered are only as good as the filter used to create them. This specification does not discuss such issues in any detail as they are readily within the skill of the person dealing in this art including the ability to determine the most appropriate slope of the cut-off characteristic.

There are a number of equalisation (EQ) methods including Digital Signal Processing techniques, but also including analogue sweep EQ that is commonly used and which exhibits variable gain and variable frequency within a fixed bandwidth. Alternatively the more complicated arrangement of parametric EQ may be applied to portions of the LFE bandwidth.

The effect is that it is possible for the total sound pressure level available from the all of the surround speakers working together can exceed that from a single dedicated LFE speaker. By sharing the LFE signal over all the surround speakers' bass linearity (low distortion) can be achieved.

By examining the internal workings of a speaker it is possible to better appreciate the effect the invention can have on a surround sound system. However, the principle could be adapted to other systems, but for the purposes of providing an example the following calculations are illustrative of the effect mentioned above.

A speaker of the subwoofer type or most others for that matter comprise some basic elements that are identified for illustrative purposes here, noting that this is not meant to be a full description of the intricacies of such devices which can be much more complicated than that described herein. A speaker has an air movement element which is generally arranged to move back and forwards along a linear path. To amplify the effect on the air that that movement creates the air movement element consists of a central piston like element connected to an annular cone shaped web which in turn is connected at its periphery to the enclosure of the speaker at the periphery of an opening in a wall of the speaker (although many alternative arrangements exist). The piston therefore has an effective diameter that pushes and pulls air to create the sound pressure wave that represents the frequency and amplitude of the audio signal presented to the speaker by the amplifier elements in the receiver 24. A wire wound coil surrounds the typically metallic piston like element and the piston is moved in response to the changing direction of a magnetic field created by the coil that has been fed the amplified signal from the receiver 24.

In an example, a 10″ subwoofer speaker might have an effective piston diameter D (equal to two times its radius R) of say 180 mm, and a linear travel of say 12 mm and a total travel of say 30 mm (for a high quality one, whereas a lesser quality and lesser cost one would be 20 mm, and the best at this time is 48 mm). It is possible to then calculate the air volume displacement of a 12″ woofer is π×R²×linear travel=3.14×(90²)×12 mm)=305,208 mm³. It is noted that the shape of the cone that is used to move the air surrounding the moving portion of the speaker is not planar and the resultant displacement not exactly cylindrical.

In comparison, a 6″ woofer (that is typically found in many surround sound full frequency speakers, might have an effective piston diameter of around 120 mm, with the same linear travel of 12 mm and maybe a maximum travel of around 22 mm. Thus the volume displacement of a 6″ speaker is 135,648 mm³ each. Which for a 5 speaker surround sound system can total 678,240 mm³ and 813,888 mm³ in a 6 speaker surround system (FL, FR, C, SL, SR, and SB).

Thus it is possible to exceed the volume displacement performance of a single 10″ subwoofer using 5 speakers each having an effective piston diameter of just 6″.

A yet further example is the use of 5 speakers having less linear travel and less diameter than assumed above, say only 9 mm linear travel and a piston diameter of 100 mm, in which case it is still possible to use only 5 speakers having a total volume displacement of 353,250 mm³ and still exceed the volume displacement of a single 10″ woofer speaker of 305,208 mm³ displacement.

Clearly, the above examples do not include any consideration of the efficiencies of the speakers throughout the range of frequencies that they are desired to operate at but that can be accommodated by appropriate equalisation treatment.

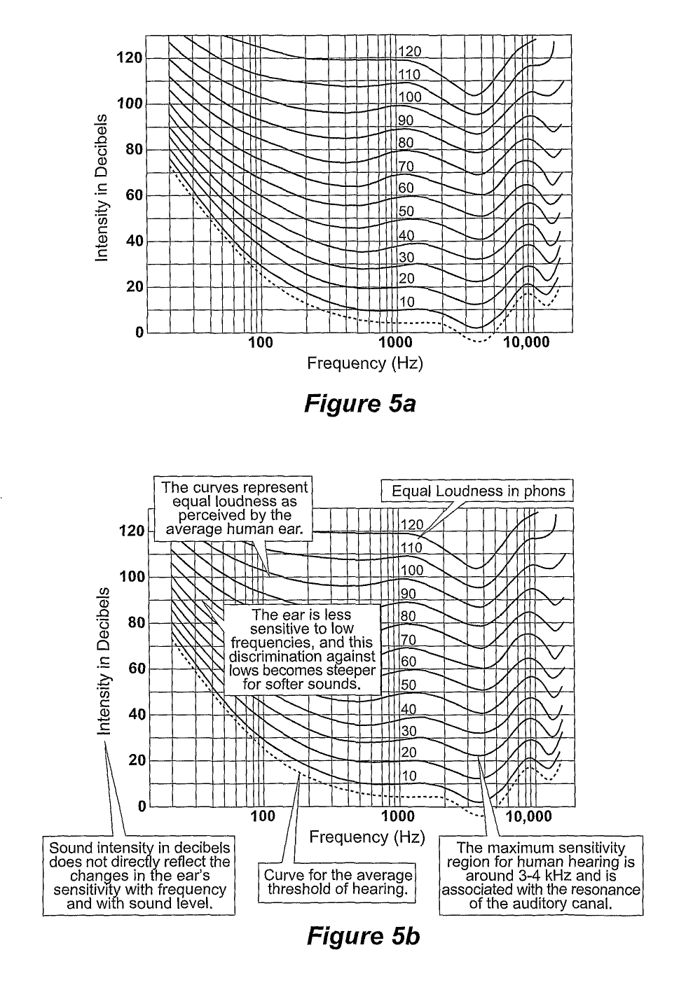

FIG. 5 depicts a plot representative of a typical human hearing response and it will be apparent that humans are more sensitive to mid-range sounds than to frequencies at the extreme high and low ends of the audible frequency spectrum. Of course we do not notice this, because we have heard sounds this way all our lives. However, as the level of sound we listen to increases, the mid-boost of the human hearing system becomes less, and the result is that high and low frequency sounds seem proportionally louder.

If in a system there are speakers that have less than a full frequency range reproduction capability it is possible to use an audio signal equaliser to boosts the level of the low frequencies as well as the LFE signals and, in this invention in one embodiment, this is done to distribute those equalized signals to the other of the surround sound signal channels, in a predetermined proportion thus eliminating the need for a subwoofer speaker.

The LFE elimination system of the invention in the particular embodiment depicted in FIG. 2 consists of a plurality of audio mixer elements 32, 34, 36, 38, 40 and 42 one for each of the audio signal outputs FL, FR, C, SL, SR and SB of the audio processor 30 except there is no such element for the LFE output.

The output of each mixer element 44, 46, 48, 50, 52 and 54 is provided to an audio amplifier 56 not unlike the receiver amplifier described previously.

The typical audio processing of such amplifiers can then be done on the FL, FR, C, SL, SR and SB audio channels and fed to respective sound transducers (speakers).

It may be that because of the characteristics of the audio amplifier, ie its frequency response etc, additional tone control will be applied to compensate (boost or attenuate) one or more of the audio channel signals.

Note that if the user wants to only listen to stereo sourced audio then it will be possible to distribute the low frequencies to all the other speakers (not those traditionally referred to a FR and FL) so as to give a low frequency ambience rather than relying solely on the FR and FL speakers to reproduce the low frequency audio elements as discussed previously.

The overall result is the provision of the LFE audio signal across all of the available/selected sound transducers (speakers) so that when required, there is a faithful reproduction of the lower frequencies at the required or near required sound pressure level as determined by the original soundtrack on the audio storage medium.

FIG. 3 depicts a further embodiment of the invention wherein there is also included an LFE signal magnitude detector 58 which monitors via input 58a the signal levels of one or more of the LFE frequencies (or bands of frequencies (not indicated in the figure)) and provides a signal on output 58b to a variable equalisation filter 60. The output signal of the magnitude detector 58 is a signal indicative of the signal level excursions within each band and the amount and type of equalisation applied to each of the bands is thus predetermined or can be changed by way of programming to the variable equalisation filter. The equalisation filter outputs an equalised LFE signal that is then summed with the pre-filtered FL, FR, C, SL, SR and SB signals from the processor 30 and provided to the audio amplifier for provision to the respective speakers for the audio channels.

A further element of the embodiment depicted in FIG. 3 is a speaker size indicator 62, likely in the form of a table of data input by the user, when installing the invention into their system, to signify to the variable equaliser element the “size” of the speaker used to transduce electronic audio signals for each of the channels in to sound pressure levels. In this example FL, FR, C, SL, SR and SB are the audio channels typically set to “small”. The input of speaker “sizes” could also be provided in the form of switches that are set by the user. Alternatively, the information may be communicated from the AV processor 30 as they are typically set by the user when setting up the AV system via an On-Screen display setting procedure.

The purpose of the signal magnitude monitoring is to allow the equalisation process to avoid the passage of signals from the LFE channel that would cause the intermediate amplifier or the audio transducers (speakers) to be swamped or suffer an over-excursion of audio signal. Avoidance of this occurrence avoids distortion and/or damage to the amplifier or speakers and a better listening experience.

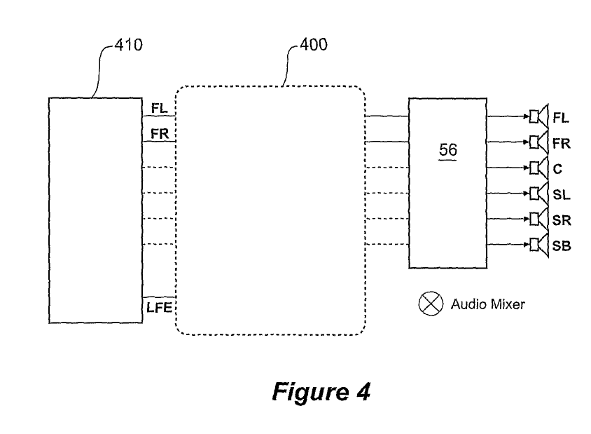

FIG. 4 is an illustration of an embodiment of the invention that does not rely on a processor 30. Thus in situations where the audio source is available and there is a desire or need to do without a sub woofer speaker, a filtering processor 310 receives the audio signal and provides all the necessary filtering to direct the low frequencies to either of the elements identified as 200 and 300 in FIGS. 2 and 3 respectively and denoted as the dotted block 400 in FIG. 4.

The provision of a separate pre-filtering element 410 allows the invention to be supplied to users that do not have or want a dedicated audio processor typically having many more features than they are likely to need for listening enjoyment of an audio source. An example of such an application could be the arrangement of a 45 rpm record turntable providing a stereo output that can be supplied to a device in accord to the invention described and illustrated in FIG. 4 the output of which is provided to a stereo valve amplifier which in turn is connected to two speakers. In this example the low frequencies in the stereo source are extracted and reintroduced into the two channels and in consequence of one possible setting of the invention the low frequencies are evened out across the two speakers. When additional speakers as are used the low frequencies are distributed across all the available speakers.

A further outcome of the use of the invention is the substantially even distribution of LFE audio within the room and that in some instances the actual and possibly the perceived total sound pressure level of the LFE channel is greater from the multiple distributed speakers than that of a single LFE speaker.

Furthermore, with regards the final listening experience, in a typical room in which home theatre sound and vision equipment is installed as opposed to the dedicated building of a home theatre room, the walls themselves help to create the low frequency standing waves that are not desirable (and without great expense to eliminate or reduce these problems become accepted aural components of such environments). Multiple bass sources, as proposed in this invention, can work within the room boundaries to provide more listening positions, sound quality and low frequency reception with dramatically reduced response ripple, i.e., dips will not be as deep, and peaks not as high. This might be different if the invention was adapted to an outdoor system, but in the examples provided this is not the case.

The use of the term channel is used in the main to refer to a band of frequencies used to supply a speaker the audio that is to be heard by a listener. The speakers referred to herein are generally labelled according to the spatial location that speaker occupies in relation to the listening environment of the listener. The handling of channels within various electronic processing devices takes into consideration the eventual use of the signal which in the case of distributed audio will depend to some degree on the spatial location of that speaker. Further more the delivery system for the audio signal follows a channel through the various pieces of equipment and processes that it undergoes (e.g. encoding, decoding, buffers, multiplexers, de-multiplexers, modulators, demodulators, transmission, switching, mixing and many other. Hence the interchangeable use of the term channel in this specification and in the relevant literature.

It will be appreciated by those skilled in the art that the invention is not restricted in its use to the particular application described, and neither is the present invention restricted in its preferred embodiment with regard to the particular elements and/or features described or depicted herein. It will be appreciated various modifications can be made without departing from the principles of the invention. Therefore the invention should be understood to include all such modifications within its scope.

1. An audio processing system for receiving filtered multiple audio channel signals which have been filtered according to settings for the filters applied to the multiple audio channels to create a low frequency channel and one or more channels excluding low frequencies intended for supply to respective multiple signal-to-sound transducers including;
a processing device for equalising the low frequency audio channel signal and distributing equalised audio low frequency signals to be summed with a filtered audio channel signal wherein the summed signal is intended to be received by a respective multiple signal-to-sound transducer.

2. An audio processing system according to claim 1 wherein the low frequency audio channel is distributed to be summed with all or predetermined ones of the filtered audio channel signals.

3. An audio processing system according to claim 1 wherein the low frequency audio channel is distributed at a level 1/n to each of n audio channels.

4. An audio processing system according to claim 1 wherein the low frequency audio channel is distributed at a predetermined level to be summed with all or predetermined ones of the filtered audio channel signals.

5. An audio processing system according to claim 1 further including an audio amplifier for amplifying each of said mixed audio channels and providing said amplified audio channel to a said signal-to-sound transducer wherein the sound pressure level generated in said sound transducers from the low frequency audio channel is independent of the predetermined listening level.

6. An audio processing system for processing multiple audio channel signals, including a pre-filtering device which receives the multiple audio channel signals and applies at least one filter to each channel according to settings for the filter to create a low frequency channel and one or more audio channels that do not have low frequencies, the one or more audio channels intended for supply to respective multiple signal-to-sound transducers; and
a processing device for equalising the low frequency audio channel signal and distributing equalised audio low frequency signals to be summed with a filtered audio channel signal wherein the summed signal is to be received by a respective multiple signal-to-sound transducer.

7. A subwoofer speaker elimination arrangement in a sound system having one or more signal-to-sound transducers to receive a respective audio channel signal including a low frequency effects signal (LFE), includes,
an LFE signal equalisation means for receiving the LFE audio channel signal output for equalisation and distribution amongst a plurality of LFE equalisation signal outputs equal in number to the number of audio channel signals less the LFE channel;
an audio signal mixer for each of said plurality of surround sound audio channel signals, each said audio mixer having a first input for receiving one of said plurality of audio channel signals not being an LFE audio channel and a second input for receiving an equalised LFE audio channel signal and an output for outputting a mixed audio signal for a respective audio signal channel.

8. A subwoofer speaker elimination arrangement according to claim 7 further including an audio amplifier for amplifying each of said mixed audio channels and providing said amplified audio channel to a said signal-to-sound transducer wherein the sound pressure level generated in said sound transducers from the LFE audio channel is independent of the predetermined listening level.

9. A subwoofer speaker elimination arrangement according to claim 7 wherein the LFE equalisation means consists of a magnitude detector for receiving the LFE audio channel signal arranged to vary the equalisation applied according to the magnitude of said LFE audio channel signal.

10. A subwoofer speaker elimination arrangement according to claims 7, 8 and 9 wherein the equalisation applied varies according to the nominated “size” of one or more of the signal-to-sound transducers.

11. A subwoofer speaker elimination arrangement according to any preceding claim wherein any LFE component of each said multiple surround sound audio channels is extracted and added to the LFE audio channel signal before equalisation.
